(19) United States
(12) Patent Application Publication
(10) Pub. No.: US 2007/0063618 A1
(43) Pub. Date: Mar. 22, 2007

(54) Ultrasonic transducer devices and methods of manufacture

(75) Inventor: George Bromfield, Salt Lake City, UT (US)

Correspondence Address: Elaine C. Stracker, 436 Harvest Circle, Vacaville, CA, 95687, US

(73) Assignee: PiezoInnovations, Salt Lake City, UT (US)

(21) Appl. No.: 11/492,144

(22) Filed: Jul. 24, 2006

Related U.S. Application Data
(60) Provisional application No. 60/702,140, filed on Jul. 25, 2005.

(51) Int. Cl. H01L 41/00

(52) U.S. Cl. 310/323.19

(57) ABSTRACT

The present invention provides for single use ultrasonic transducers for use in surgical and dental applications. Specifically, the invention provides transducers comprising one or more of the following features, an active piezo ceramic material that contains less than 2% lead; piezo materials with a low Curie temperature, a high compressive bias force applied to the piezo ceramic elements, a bias bolt sub-assembly that includes a component assembled with a low-temperature glass-transition point filled epoxy material, and/or a permanently attached end effector with a self-locking taper.

### CROSS REFERENCE TO RELATED APPLICATIONS

This application claims priority under 35 U.S.C. §119 from Provisional Application Ser. No. 60/702,140, filed Jul. 25, 2005, the disclosure of which is incorporated herein by reference.

### FIELD OF THE INVENTION

The invention relates generally to the field of transducers. More specifically, this invention relates to surgical and dental transducers suitable for single use applications.

### BACKGROUND

Since 1996, evidence has been increasing for a causal relationship between ongoing outbreaks in Europe of a disease in cattle, called bovine spongiform encephalopathy (BSE, or ‘mad cow’ disease), and variant Creutzfeldt-Jakob (vCJD). There is now strong scientific evidence that the agent responsible for the outbreak of prion disease in cows, BSE, is the same agent responsible for the outbreak of vCJD in humans. Both disorders are invariably fatal brain diseases with unusually long incubation periods measured in years, and are caused by an unconventional transmissible agent. For surgical and dental patients there is a risk that the disease can be transmitted by contaminated re-usable surgical instruments. The prion is known to be resistant to sterilization by steam autoclave and penetrates the micro structure of metal components. Since the disease affects the brain surgical procedures that expose neurons to direct and indirect contamination to the prion carry an enhanced risk of vCJD. Brain surgery using ultrasonically activated soft tissue aspirators and eye surgery including ultrasonic phacoemulsification and retinal repair fall into this category. Although the reusable transducer is attached to a single use end effector it is susceptible to contamination since ablated tissue and cataract fragments are aspirated though a center lumen.

There is therefore a general need in the art for single use transducers. These transducers should be cost effective and designed to undergo degradation upon sterilization to prevent reuse of a single use item.

### SUMMARY

The present inventions provides single use ultrasonic transducers for use in surgical and dental applications. One aspect of the invention comprises transducers that have an active piezo ceramic material that contains less than 2% lead. Thus, significantly reducing the disposal problems associated with the disposal of lead containing materials.

Another aspect of the invention comprises transducers having an active piezo ceramic material that has a low Curie temperature, such that the material of the piezo ceramics in the transducer would seriously degrade upon exposure to steam sterilization temperatures of approximately 137° C. Thus, preventing re-use of a single use transducer.

Another aspect of the invention is the application of high compressive bias force to the piezo ceramic elements for use in a single use device. Generally, a high compressive bias in a reusable transducer is undesirable as the performance will degrade over time due to fluctuations in temperature, such as that occurring from steam sterilization. However, for a single use device not subject to these temperature fluctuations, performance of the device is actual improved upon use of a higher bias force applied to the piezo ceramic elements.

Another aspect in accordance with the present invention is a bias bolt sub-assembly that includes a component assembled with a low-temperature glass-transition point filled epoxy material. Use of a low-temperature glass-transition point filled epoxy material renders a single use device inoperable upon sterilization, as the epoxy will soften and thereby reduce the level of the stack bias stress in the transducer. This results in a significant reduction in the performance of the transducer

Yet, another aspect of the invention is a method permanently attaching an end effector to a single use transducer to prevent re-use of the device. A self-locking taper on the end of the end effector is provided to prevent removal of the end effector after use.

### BRIEF DESCRIPTION OF THE DRAWINGS

FIG. 1 is an illustration of a phacoemulsification transducer coupled to a horn with an needle attached.

FIG. 2 is an illustration of a bolted dumbbell half wavelength transducer.

FIG. 3 is an illustration of a transducer with a capacitor connected to it for measuring charge using an electrometer.

FIG. 4 is a block diagraph showing the connection of the transducer to a system for purposes of high power testing the transducer.

FIG. 5 is a graph of the plot of velocity versus power measurements for a BaTiO₃ and a PZT III transducer.

FIG. 6 is a graph of the plot of volts versus velocity measurements for a BaTiO₃ and a PZT III transducer.

FIG. 7 is a graph of impedance at resonance and the resonant frequency versus piezo stress for a transducer.

FIG. 8 is a graph of the changes in the d33 constant due to bias stress at various temperatures.

FIG. 9 is an illustration of a half resonant section of a transducer without the horn attached.

FIG. 10 is an illustration of a single use transducer assembly within a housing.

FIG. 11 is an illustration of two needles for attachment to a handpiece one with a screw thread and the other self-locking taper.

Reference will now be made in detail to embodiments of the present disclosure. While certain embodiments of the present disclosure will be described, it will be understood that it is not intended to limit the embodiments of the present disclosure to those described embodiments. To the contrary, reference to embodiments of the present disclosure is intended to cover alternatives, modifications, and equivalents as may be included within the spirit and scope of the embodiments of the present disclosure as defined by the appended claims.

### DETAILED DESCRIPTION OF SPECIFIC EMBODIMENTS

Unless otherwise indicated, all numbers expressing quantities and conditions, and so forth used in the specification and claims are to be understood as being modified in all instances by the term “about.”

In this application, the use of the singular includes the plural unless specifically stated otherwise. In this application, the use of “or” means “and/or” unless stated otherwise. Furthermore, the use of the term “including,” as well as other forms, such as “includes” and “included,” is not limiting. Also, terms such as “element” or “component” encompass both elements and components comprising one unit and elements and components that comprise more than one subunit unless specifically stated otherwise.

The term “coupled to” means to be attached or connect to directly or indirectly or to be incorporated within.

An urgent need exists for a low-cost, single use transducer for neurosurgery and ophthalmic surgical procedures. Given a choice, marketing information indicates that some patients would be prepared to pay a premium for single use transducers for dental and general surgical procedures. The high volume manufacture and disposal of single use transducers poses an environmental problem since the motive power for these ultrasonic devices is currently dependent on a 60%-lead-containing family of piezo ceramics. European Union directives have identified this as a potential problem. Regardless of the enactment of legislation there would be considerable advantage in marketing a single use ultrasonic surgical device that did not contain lead-based piezo.

Although the manufacture of ultrasonic transducers for surgical applications is strictly regulated in the USA and the EU, a number of companies specialize in reverse engineering the transducers supplied by the original equipment manufacturer. These after-market devices and repairs to the original transducer pose a problem with respect to control system compatibility and performance. A number of manufacturers have combated this problem by incorporating micro-chips within the transducer or the electrical connector. This would not be appropriate for single-use designs, as it would result in an unacceptable increase in complexity and cost of manufacture. A need therefore exists for specific transducer design features that limit the transducer and attached end effector to single use. A need also exists to render the transducer inoperable and beyond economic repair should any attempt be made to steam sterilize it after use.

Various aspects of the invention provide ultrasonic transducers for single use that address the problems discussed above. One aspect in accordance with the present invention is to use an active piezo ceramic material contains less the 2% lead. In a preferred embodiment, the piezo ceramic material of the transducer contains no lead.

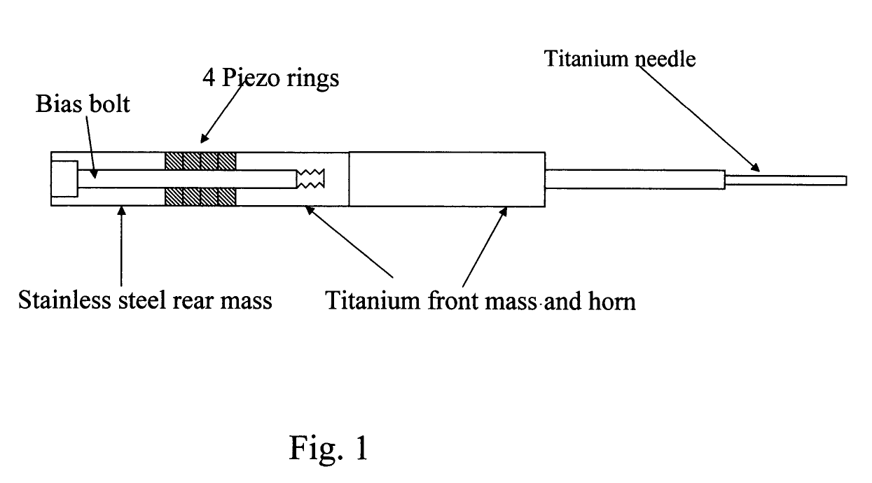

For illustration purposes, a generic ultrasonic phacoemulsification (cataract removal) handpiece transducer will be used as an example in accordance with the present invention for purposes of illustration only and not limitation. Those of skill in the art will recognize that the aspects of the invention can be used in a variety of different transducers. An illustration of a phacoemulsification transducer is shown if FIG. 1

An alternating voltage is applied to the four piezoceramic rings. The piezo converts electrical energy into mechanical energy and results in high strain, small longitudinal displacements within the stack of piezo rings. At the longitudinal resonance frequency, the small displacements within the piezo drive stack are amplified by the Q factor of the transducer and also by the cross section area gain within the titanium horn. The performance of the transducer and end effector can be analyzed by method known by those of skill in the art. Alternatively, they can be analyzed by using PiezoTran™. PiezoTran™ is a computer model that is based on acoustic transmission line theory. PiezoTran™ applies a user defined constant voltage and can incrementally sweep the frequency from below the resonance frequency to above the anti-resonance frequency. For a system of analogues used in the electrical equivalent circuit of the transducer, it can be shown that the velocity of the transducer end effector is proportional to input current i. The computer model can therefore be used to evaluate piezo-related changes in the relationship between input current and end effector tip velocity.

Existing re-usable ultrasonic transducers for high power surgical and dental applications use PZT (lead zirconate titanate) ceramic to provide the motive force. PZT materials are formulated for specific applications and the US Navy has specifications designated as Navy type I and Navy type III that are applicable for high power applications. The attributes of these types of PZT are low electrical and mechanical losses, high coupling coefficient, high Curie temperature and small age related changes to the piezo properties. Low electrical and mechanical losses are important as they reduce the heat generated within piezo drive stack. For most existing medical and dental transducer designs, the mechanical losses limit the power output and especially for applications without liquid cooling. A high coupling coefficient is important because it reduces electrical impedance and lowers the drive voltage. It also provides increased frequency separation between the resonance frequency Fr (minimum impedance, Zmin) and the anti-resonance frequency Fa (maximum impedance, Zmax). The frequency separation (Fa-Fr) is known as delta F or phase margin and can impact the accuracy of some system control algorithms. The computer model calculates the coupling coefficient from the piezo material constants that include g₃₃. The Curie temperature is the absolute maximum exposure temperature for any piezo ceramic. When a ceramic is heated above the Curie point all piezoelectric properties are lost. In practice, the operating temperature must be substantially below the Curie point. At elevated temperatures, the aging process increases, the electrical losses increase, efficiency decreases, and the maximum safe stress level is reduced.

Barium titanate (BaTiO₃) was the first piezoelectric ceramic to be developed commercially, and came into wide use during the 1950s . Barium titanate (BaTiO₃), as discussed further below, however, because of its properties was not conducive for use in re-useable transducers for medical and dental applications. The lead free piezo BaTiO₃ was replaced in the 1960s by a material with superior performance, lead zirconate titanate (PZT). The properties of a new lead free piezo (LF4T) have been recently published in the magazine Nature by Toyota Central R&D Laboratories, Inc. and the DENCO Corporation. Some of the important properties are compared in the table below.

| | Curie | Electrical | | | |
|---|---|---|---|---|---|
| Piezo | Temp | loss | Mechanical | Coupling | Dielectric |
| Material | ° C. | Tan δ | Q | Coefficient kₚ | constant |
| BaTiO₃ | 115 | .005 | 600 | 0.31 | 1220 |
| PZT I | 320 | .004 | 500 | 0.71 | 1300 |
| PZT III | 300 | .002 | 1000 | 0.6 | 1100 |
| LF4T | 253 | | | 0.61 | 1570 |

Although as can be seen from the chart, the properties of BaTiO₃ differ significantly from the materials used in re-useable transducer, because it is lead free, cost competitive with PZT, generally available, and its properties are suitable for use in a single use device, as discussed in detail below, this material is a preferred embodiment of this aspect of the invention.

When designing a new transducer that includes a horn and end effector, it is a good practice to optimize the design of the half wave active dumbbell section before attaching the horn and end effector. This is especially important if a different type of piezo material is being considered, such as replacing PZT with barium titanate.

A comparison of the relative quiescent power loss is of most interest, as mechanical losses put a practical limitation on end effector displacement. For most medical and dental transducers, the voltage that is applied under extreme loading conditions is still relatively low compared with sonar transducers. For the purposes of this example, the transducers were tested in air. This effectively reduces the dissipated or radiated power to zero. The voltage will be reduced to very low level that is proportional to the impedance associated with the mechanical losses in the piezo material and the assembly. For a specific value of end mass displacement the quiescent power loss is calculated using the formula: power=volts×current×the cosine of the phase angle. For a comparison based on quiescent power, the electrical tan δ losses can be ignored. If required, the tan δ loss can be quantified separately from the mechanical losses by adjusting the test frequency to correspond with anti-resonance and applying the maximum value of operational voltage. At this frequency, the impedance will be very high and the end mass displacements very low.

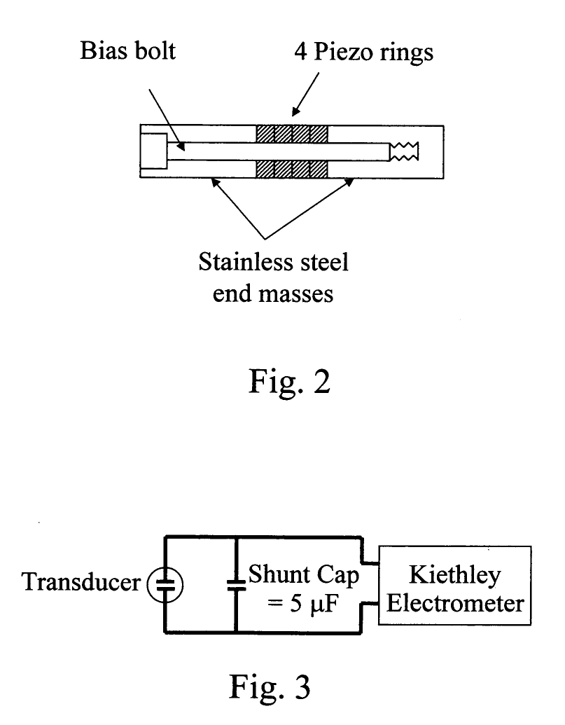

The advantage of using the dumbbell transducer is that the effect of variables such as bias stress and temperature can then be evaluated in isolation from the influence of horns and end effectors. For purposes of this example, a bolted dumbbell half wavelength transducer, as illustrated in FIG. 2, was used to evaluate the performance of BaTiO₃ and PZT III. The 4 BaTiO₃ rings used in the transducer had an outside diameter of 9.5 mm, an internal hole diameter of 4.4 mm and a thickness of 2.54 mm. The 4 PZT III rings had an outside diameter of 9.5 mm, an internal hole diameter of 5 mm and a thickness of 2 mm. The end masses were stainless steel and a piezo bias stress of 35 MPa was applied by means of a socket head high tensile steel bolt. The nominal half wavelength resonance frequency of this transducer was 40 kHz. In the final transducer design the front mass of the dumbbell will be incorporated with the horn as a single component.

The performance of the dumbbell transducers can be determined under both static and dynamic test conditions. The dumbbell transducers were assembled and the bias bolt was connected so that it held the components together but did not apply a significant pre-load. The dumbbell transducer was then placed in a hydraulic press that included a calibrated load cell. The load was increased up to a maximum value that corresponded with a stress in the piezo rings of 35 MPa. The charge was measured using a very high impedance electrometer, in a configuration such as is shown in FIG. 3. A low loss 5 μF capacitor was connected in parallel with the transducer in order to reduce the voltage. The voltage (Vmax) corresponding to a pre-stress in the piezo of 35 MPa was determined for both the BaTiO₃ and PZT III transducers. The transducers were removed from the press, reconnected to the electrometer, again as shown in FIG. 3, and torque was applied to the bias bolt until the previously measured value of voltage (Vmax) was achieved.

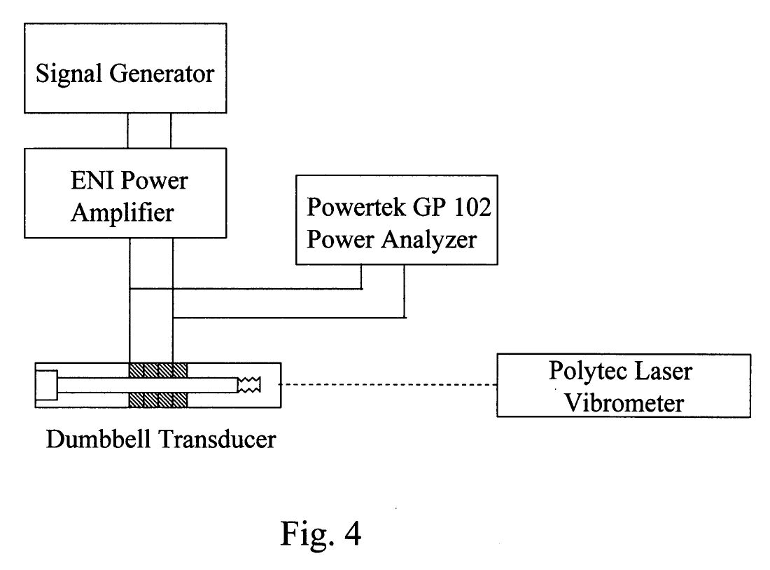

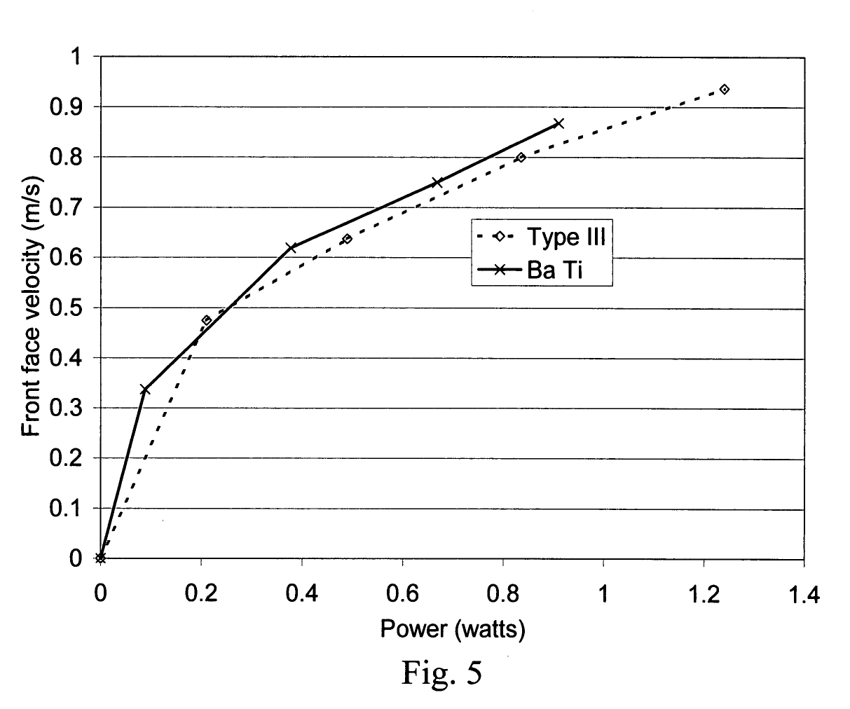

After applying torque to the bolt, the transducers were allowed to stabilize for 24 hours. The transducers were tested at a low power using an impedance analyzer (HP4194A or equivalent). Measurements taken included the resonance frequency (fᵣ), the anti-resonance frequency (fₐ), the minimum impedance (Zₘᵢₙ) and the capacitance (C_{lf}). The transducers were then high power tested using the instrumentation set-up as shown in FIG. 4. The signal generator voltage was slowly and incrementally increased while continuously adjusting the resonant frequency in order to maintain a zero phase angle between the voltage and current. At convenient power increments, the velocity of the dumbbell transducer end mass was measured by the laser vibrometer and the current, voltage, phase angle, frequency, and power were measured using the power analyzer. The temperature of the end mass was also measured and limited to a maximum of 600° C. to avoid damaging the piezo rings. FIG. 5 shows that over a limited power range the quiescent power loss performance of the BaTiO₃ and PZT III transducers were similar. Thus, the use of a BaTiO₃ piezo ceramic material in a transducer is a viable option.

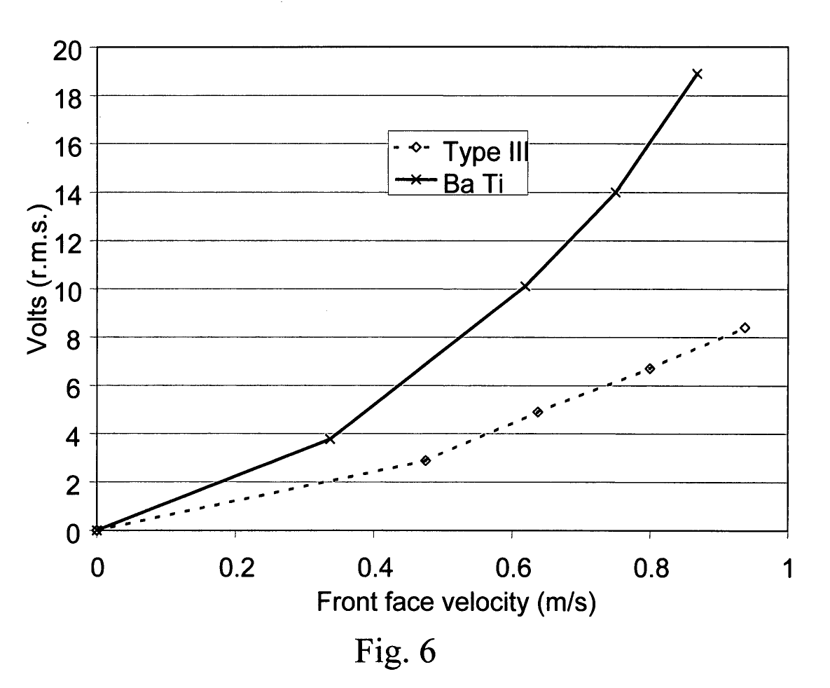

The main disadvantage of barium titanate is the relatively low value of coupling coefficient that results in a higher operating voltage as shown in FIG. 6. In the experiment, the thickness of the two types of rings used differed, the BaTiO₃ rings were 2.54 mm thick and the PZT III rings were 2 mm thick. Therefore, for valid comparison, to accurately compare the data, the BaTiO₃ volts need to be correspondingly reduced and the actual ratio is approximately 2:1. As the same velocity can be attained by modifying the voltage, the BaTiO₃ can be used as a substitutable material to the PZT III in a transducer.

Phacoemulsification transducers and other similar designs for surgical and dental procedures are usually steam sterilized after each use. Depending on the application, they can be used as many as 1000 times before they reach the end of their useful life. The steam autoclave operates at a typical temperature of 137° C. and this repeated temperature cycling degrades the properties of the transducer piezo components. Measurements of a proprietary design of medical transducer indicated that the piezo g₃₃ piezo constant of the PZT III degrades from a new nominal 10 day old value of 0.025 VmN⁻¹ to 0.014 VmN⁻¹ at the end of useful life. The g₃₃ degradation of a single-use design using BaTiO₃ would be less providing the ambient temperature remained relatively stable and close to 20° C. It would degrade with time after polarization and after a 1000 day period, it would be approximately 0.0105 VmN⁻¹. The applied voltage for a transducer operating at constant power is inversely proportional to the value of the piezo g₃₃. Therefore, the increase in voltage between an end-of-life reusable transducer with PZT III and a new single use transducer with 1000 day old BaTiO₃ piezo would be approximately 1.5:1

The PiezoTran™ computer analysis of a generic phacoemulsification transducer is used to compare a single-use barium titinate piezo design with a baseline re-usable new PZT design. The computer model assumes both transducers have a needle tip displacement of 100 microns peak to peak and identical tip radiation load such that the Q factor is 154. The data from the computer modeling of these systems is shown in the following table.

| | Capacitance | Delta F | K | Current | | Power |
|---|---|---|---|---|---|---|
| Transducer | nF | Fa-Fr | effective | Amps r.m.s | Volts V rms | watts |
| PZT | 1.61 | 480 | .122 | 0.1089 | 92 | 12.5 |
| BaTiO₃ | 1.46 | 140 | .089 | 0.072 | 174 | 12.6 |

Although the performance of the single-use barium titinate piezo design falls short of the PZT design with respect to the higher applied voltage and lower delta F, according to the data, it has the ability to provide adequate single-use performance. Moreover, the single-use barium titinate piezo design can be further optimized. For example: the titanium horn could be redesigned with less mechanical gain and this would increase delta F and increase the voltage.

A second aspect of the present invention relates to the use of a low Curie temperature active piezo ceramic material that will significantly degrade upon exposure to steam sterilization temperatures of approximately 137° C. The piezo ceramic elements provide the motive force for ultrasonic surgical and dental transducers. A general rule of thumb for maintaining performance of the transducers is that the transducers should not be exposed to temperatures that exceed half the value of the Curie temperature. As temperature is increased above this temperature, there is a progressive and permanent degradation of the coupling coefficient and other key piezo properties. The reduction in the coupling coefficient will result in a significant increase in the impedance at the resonance frequency and a significant decrease in delta F (Fa-Fr). This will result in an unstable situation that would automatically be detected by the control system. It would be interpreted as an error condition that would almost certainly trigger an alarm and automatically shut off power to the transducer.

Within the context of a single use transducer, the use of a low Curie temperature piezo would be a key factor in preventing any attempt to re-use the transducer by attempting to steam sterilize it after the initial use. The piezo components are critical to performance and represent a significant fraction of the parts and labor cost associated with the manufacture of the transducer stack sub-assembly. In conjunction with a number of other design features, the use of low Curie temperature piezo would help ensure that after one use the transducer was beyond economic repair. This would encourage users to follow the correct disposal instructions that are appropriate for this type of surgical instrument.

Although barium titanate is the preferred material for this application as it is lead free, there are other types of high performance piezo that contain lead and have a low Curie temperature. Thus, for some very specialist endoscopic surgical procedures, the use of these materials might be a key enabling technology with respect to the size of the transducer. For the US market, a single use device would be appropriate. One such material developed by Piezo Technologies and designated as Kezite 300, has ideal properties for this application with a Curie temperature of 217° C. In one embodiment, a relaxor based solid solution piezo material that has a Curie temperature below 250° C. is used. In other embodiments, preferably, the piezoelectric materials used in this aspect of the invention have a Curie temperature of 250° C. or below, more preferably 200° C. or below, even more preferably 140° C. or below, and most preferably 115° C. or below.

A third aspect in accordance with the present invention relates to the application of a high value of compressive bias force to the piezo ceramic elements. Piezoceramic is inherently weak in tension. Langevin style transducers have a stack of piezo elements as shown in FIG. 1. Under high power operation, the cyclic stress within the piezoceramic results in high tensile force unless a steady state bias force is applied. Most Langevin style transducers have a bolt that passes through the center of the piezoceramic rings. The bias force is applied by tightening the bolt to a specific value of torque or preferably by tightening the bolt and measuring the electrical charge generated by the stack of piezoceramic rings.

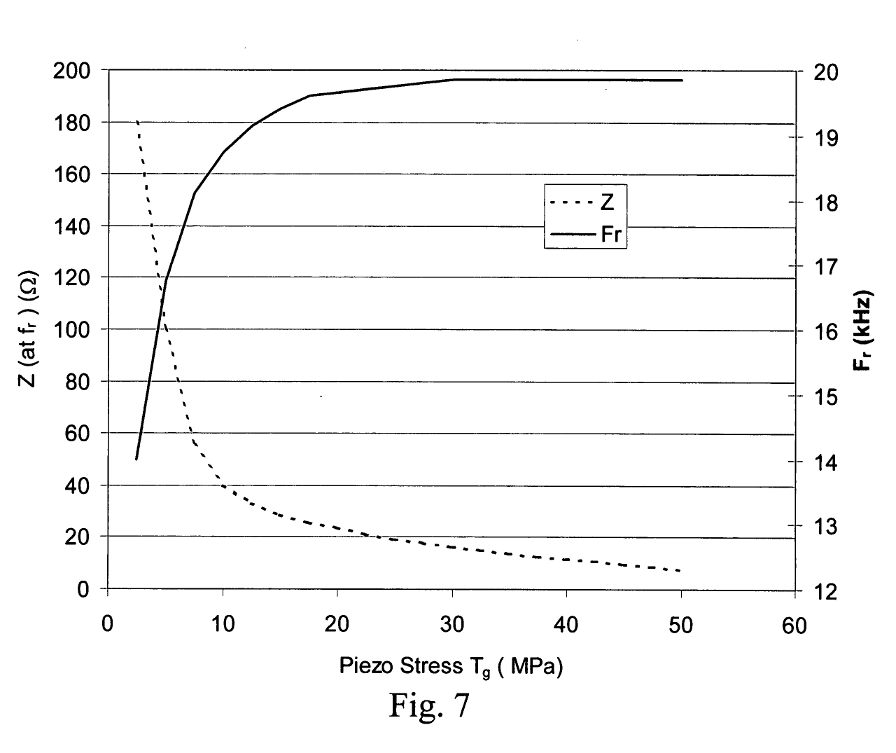

In the 1960s, Berlincourt is credited with the seminal work relating to the characterization of a piezoceramic. He produced the graph shown in FIG. 7 that relates the applied level of transducer bias stress to changes in the resonant frequency and impedance at resonance.

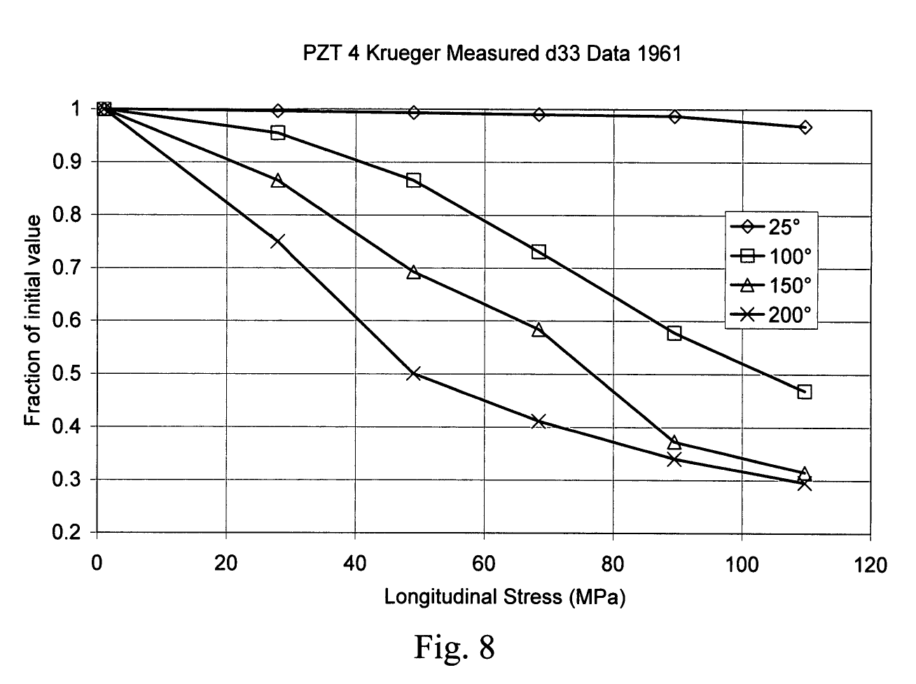

As these measurements relate to a test transducer in air, the impedance at resonance (Z at fᵣ) has a low value that decreases with increasing values of bias stress (T_{g}). For many applications, transducers are characterized in air prior to operational use. During this test, the end effector is driven at maximum displacement and the generator provides a level of quiescent power that is proportional to Z at fₛ. The unwanted heat generated within the piezoceramic drive stack is proportional to the quiescent power and reducing the Z at fᵣ will result in a beneficial improvement in electro-mechanical efficiency. However, the bias stress applied to re-usable transducers is typically limited to levels between 25 MPa and 35 MPa. The reason is that the performance of a transducer with high levels of piezoceramic bias stress degrades significantly when subjected to fluctuations in temperature. These changes can occur as a result of extended high power operation or from external factors such as steam sterilization. Krueger measured the changes in the piezoceramic d₃₃ constant that occur due to the combination of bias stress and temperature change and his data has been reproduced in the graph shown in FIG. 8. As the coupling coefficient is proportional to the d₃₃ constant, the performance of a transducer with 80 MPa of bias stress would be seriously degraded if it were subjected to a 1370° C. steam sterilization temperature.

For single use transducers, however, applying bias stress levels between 60 MPA and 80 MPa would improve operational performance provided that the transducers are not exposed to large changes in temperature prior to operational use. This can be accomplished by using a low duty cycle pulse mode during the high power testing during manufacture. Thus, while the use of a high bias stress is undesirable in a re-usable transducer that is subject to significant temperature fluctuations, its use in a single use device not subject to these temperature constraints would be advantageous. For example, a single-use barium titinate piezo transducer with a high bias level would have an improved operational performance compared to the same transducer without the high bias level.

Additionally, it is known that the application of high values of transducer piezo stack bias stress improves the performance of stacks that are assembled using the “dry assembly” method. The epoxy assembly method has been optimized for bias stress levels between 25 MPA and 35 MPa and this adds significant time and cost to transducer sub-assembly. The epoxy method has the additional benefit of coating the piezoceramic and preventing performance degradation as a result of moisture ingress. However, as the single use transducer will be stored in a controlled dry environment, the epoxy vacuum impregnation of the piezoceramic stack will be unnecessary.

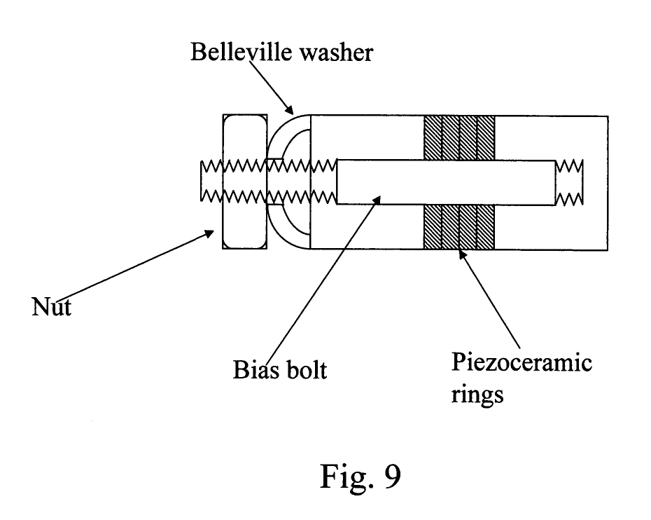

Another aspect of the present invention is to an assembly method and the resultant transducer from this assembly that is optimized for a single use low cost medical application. This aspect of the invention relates to design features that would render the transducer inoperable should any attempt be made to steam sterilize the device. Two examples are provided to illustrate this aspect of the invention. In these examples, a pre-loaded force is applied to components bonded with a low temperature glass transition point epoxy material during the assembly procedure. The method is applied to a transducer as shown in FIG. 9. FIG. 9 is a half wave resonant section of a transducer without the horn attached. The function of the center bias bolt is to apply a uni-axial compressive force across the stack of piezoceramic rings. Force is exerted as toque is applied and this causes the bolt to stretch by a very small amount, typically 20 to 100 microns. The assembly procedure relating to the application of the piezoceramic pre-stress is as follows: 1) apply a mold release silicone spray to the nut of the transducer; 2) assemble the belleville washer over the exposed thread of the bias bolt; 3) loosely tighten the bolt; 4) fill the void between the front face of the nut and the rear face of the transducer rear mass with a filled epoxy ensuring the belleville washer is completely encapsulated; 5) allow the epoxy to cure; and 6) apply torque to the nut.

Armstrong epoxy adhesive A-2/E is a filled epoxy that has a glass transition temperature of 84° C. It has a high value of shore hardness and is ideally suited for this application. Although, other epoxies can be used. The function of the cured epoxy is to prevent the belleville washer from compressing as torque is applied to the nut. Should the assembly be exposed to a temperature above 84° C., the epoxy will progressively soften and thereby significantly reduce the level of stack bias stress. This change would be permanent and irreversible and would degrade the transducer characteristics to an extent that the transducer would not function.

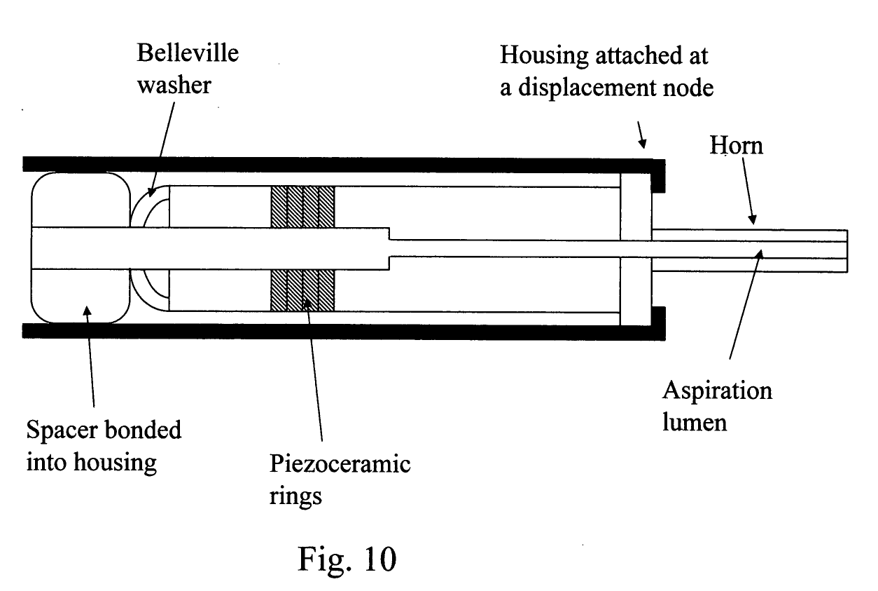

As a second example, an alternative transducer assembly with this feature is shown in FIG. 10. In this transducer assembly, the components are assembled and bonded within a housing. The advantage of this method is that the bias force is applied by belleville washers. Although the diagram shows one washer additional washers can be cascaded together in order to increase the combined stiffness to the required level. The method of assembly relating to the application of piezoceramic pre-stress is as follows: 1) using a suitable internal alignment rod, assemble the components prior to insertion in the housing; 2) prepare the bonded surfaces within the housing and the external surface of the rear spacer; these surfaces should be locally abraded and degreased using a suitable solvent; 30) apply a filled epoxy, such as, for example, but not limitation, Armstrong epoxy adhesive A-2/E to the external surface of the rear spacer and insert the sub-assembly into the housing; 4) clamp the housing in a suitable fixture and apply a compressive bias force to the rear surface of the rear spacer; 5) maintain the compressive force at a constant level and allow the epoxy to cure; and 6) remove the compressive force and internal alignment rod.

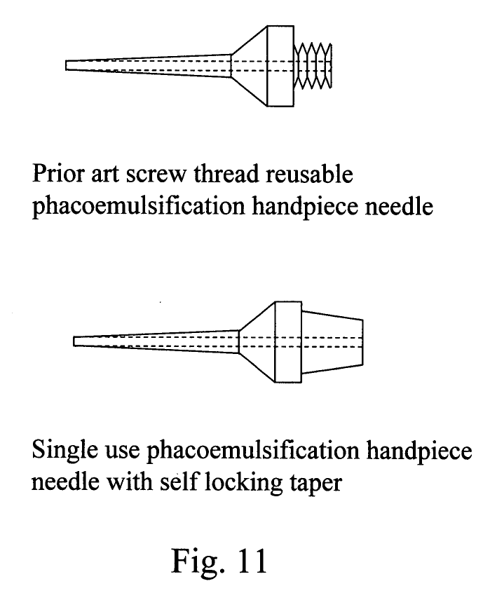

Yet, another aspect of the present invention relates to a methodology for permanently attaching the end effector to a transducer assembly. The design of the end effector is dependent on the application. End effectors are known by a variety of application specific names that include, but are not limited to, needle, probe, insert, waveguide, and cannula. Typically, screw threads are used to attach the end effector to the transducer. FIG. 11 illustrates a comparison between a screw thread needle used for phacoemulsification and a self-locking taper which is a feature of this invention.

The screw thread provides the methodology for attachment to the horn that is a part of the transducer assembly. For most applications, the end effectors are single use items and are individually packed in a sterile package. They are attached by using special tools that control the amount of torque that is applied. This is important because acoustic energy has to be efficiently coupled from the horn and the application of ultrasonic energy will tend to loosen the screw. Most transducer control systems have algorithms that can detect a loose tip condition.

For single use transducers, the complexity and cost of machining an integrated horn and end effector would be prohibitively high for most applications. However, for single use applications, there are a number of disadvantages in using a screw thread. The acoustic loss within screw threads is a known problem that causes heat generation at high values of cyclic stress. The root of thread form within the horn results in a discontinuity that causes stress concentration and the outside diameter of the horn often has to be increased to avoid tensile failure. For a phacoemulsification application, the threads are a potential source of metal particle exfoliation. Permanent attaching the end effector to the horn of the a single use transducer, will not only eliminate these problems, but also make it more difficult to salvage and re-use either the end effector or horn component of the transducer assembly.

There is therefore a need for a method of permanently attaching an end effector to a single use transducer that also reduces the cost of manufacture, improves acoustic energy coupling, reduces the risk of metal particle exfoliation and increases the difficulty of salvaging and reusing transducer components.

The use of a self-locking taper (sometimes referred to as a self-holding taper) is an established method of providing an interference fit between two metal components. The upper limit on the taper angle is 16° and typically taper angles are 8°. Use of a self-locking taper on a needle was validated using a transducer that had an aluminum horn with a diameter at the distal tip on 0.250 inches. A titanium alloy bar that had a diameter of 0.250 inches was permanently attached to the aluminum horn by means of a Morse self-locking taper. The length of the titanium bar was adjusted such that it corresponded with one half wavelength at the resonance frequency of the transducer. The transducer was driven at high power and the joint remained intact with no measurable increase in temperature.

The foregoing examples illustrate various aspects of the invention and practice of the methods of the invention. The examples are not intended to provide an exhaustive description of the many different embodiments of the invention. Thus, although the foregoing invention has been described in some detail by way of illustration and example for purposes of clarity and understanding, those of ordinary skill in the art will realize readily that many changes and modifications can be made thereto without departing form the spirit or scope of the invention.

What is claimed is:

1. A single use transducer for ultrasonic surgical and dental applications comprising:
a) a rear mass;
b) a piezoelectric material coupled to the rear mass, comprising less than 2% lead by weight;
c) a horn coupled to the piezo material; and
d) an end-effector coupled to the horn.

2. The single use transducer of claim 1, wherein the piezoelectric material is barium titanate.

3. The single use transducer of claim 2, wherein the piezoelectric material has a Curie temperature between 115° C. and 140° C.

4. The single use transducer of claim 1, wherein the piezoelectric material is a relaxor based solid solution piezoelectric material that has a Curie temperature below 250° C.

5. The single use transducer of claim 1, further comprising a low-temperature glass transition point epoxy material, wherein the epoxy material encapsulates a Belleville washer, within a bias bolt sub-assembly in the transducer and thereby maintains a compressive force.

6. The single use transducer of claim 5, wherein the epoxy material is Armstrong epoxy adhesive A-2/E.

7. The single use transducer of claim 1, wherein the transducer has a piezoceramic bias stress level between 50 MPa to 80 MPa.

8. The single use transducer of claim 1, wherein the end effector is permanently attached to the horn.

9. The single use transducer of claim 8, wherein the end effector is attached via a self-locking taper that has a taper angle less than 16 degrees.

10. A single use transducer for ultrasonic surgical and dental applications comprising
a) a rear mass;
b) a piezoelectric material having a high compressive bias stress level coupled to the rear mass;
c) a horn coupled to the piezo material; and
d) an end effector coupled to the horn; and

11. The single use transducer of claim 10, wherein the high compressive bias stress level is between 50 MPa and 80 MPa.

12. The single use transducer of claim 10, further comprising a bias bolt sub-assembly with a Belleville washer.

13. The single use transducer of claim 12, further comprising a low-temperature glass transition point epoxy material, wherein said epoxy material encapsulates the Belleville washer within the bias bolt sub-assembly and thereby maintains a compressive force.

14. The single use transducer of claim 13, wherein the epoxy material is Armstrong epoxy adhesive A-2/E.

15. The single use transducer of claim 14, further comprising an external housing

16. The single use transducer of claim 15, wherein the compressive force is applied to a sub-assembly anchored in the external housing.

17. The single use transducer of claim 15, wherein the piezoelectric material has a Curie temperature between 115° C. and 140° C.

18. The single use transducer of claim 15, wherein the end effector is permanently coupled to the horn via a self-locking taper.

19. A single use transducer for ultrasonic surgical and dental applications comprising
a) a rear mass;
b) a piezoelectric material having a high compressive bias stress level between 50 MPa to 80 MPa coupled to the rear mass; wherein the piezoelectric material is lead free and has a Curie temperature between 115° C. and 140° C;
c) a horn coupled to the piezo material;
d) an end effector permanently coupled to the horn; and
f) a low-temperature glass transition point epoxy material, wherein said epoxy material encapsulates a Belleville washer, within a bias bolt sub-assembly in the transducer; and anchors the sub-assembly in the housing and thereby maintains a compressive force.

20. The single use transducer of claim 19, wherein the piezoelectric material is barium titanate.
